(19) United States
(12) Patent Application Publication
(10) Pub. No.: US 2011/0188187 A1
(43) Pub. Date: Aug. 4, 2011

(54) DEVICE WITH AUTO-SLIDE KEYPAD

(75) Inventors: Ricky Barnett, Hertfordshire (GB); Brian Davidson, Surrey (GB)

(73) Assignee: NOKIA CORPORATION, Espoo (FI)

(21) Appl. No.: 13/061,497

(22) PCT Filed: Aug. 29, 2008
(86) PCT No.: PCT/EP08/61439

§ 371 Date: Feb. 28, 2011

(51) Int. Cl. H05K 7/00; A47B 96/00; B23P 23/00

(52) U.S. Cl. 361/679.01; 312/323; 29/401.1

(57) ABSTRACT

A portable electronic apparatus comprises a base, first and second parts moveably connected to the base, and a mechanism coupling the first and second parts. The mechanism is configured such that when one of the first or second parts is moved relative to the base, the other of the first or second parts moves relative to the base. One of said first and second parts is configured to tilt to an inclined position relative to the base.

The present invention relates to an apparatus having a base and cooperating moveable parts coupled thereto, and more particularly, to a portable electronic device with a cooperating moveable display part and keypad part.

Portable electronic devices are known, such as mobile phones and PDAs, which generally comprise a body having a display unit and keypad area. In some known devices, a display unit including the display screen and/or a keypad including the keys are provided on the electronic device mounted to a main body thereof to be moveable relative to the main body and/or each other, so that the display unit and/or keypad can be moved between an operative position during use of the device, and a generally more compact storage position for when the device is not being used.

One such known device is disclosed in the applicant's earlier patent application U.S. Pat. No. 6,748,249 and comprises a portable electronic device having a touch screen and a sliding lid slidingly mounted to a body of the device and coupled together such that movement of one of the touch screen and sliding lid between a storage and an operative position causes corresponding movement of the other of the touch screen and sliding lid between the storage and the operative position. In all embodiments disclosed, the screen and lid are moveable linearly in the same two-dimensional plane.

Another such device is disclosed in another of the applicant's earlier patent applications WO 2007/140911, which discloses a portable electronic device comprising three layers slidably connected to one another, such that the top layer can be slid relative to the middle layer to selectively expose or cover a keypad on the middle layer, and the bottom layer can be slid relative to the middle layer to selectively expose or cover a keypad on the bottom layer. As with the device of U.S. Pat. No. 6,748,249 described above, each of the three layers is moveable in the same two dimensional plane as each other.

A third known device is disclosed in U.S. Pat. No. 7,330,548 which comprises a mobile electronic device having a main housing with first and second upper housing covers slidably mounted to the main housing to selectively cover or expose a display screen provided on the main housing. The first and second upper housing covers are connected to one another by a mechanism such that movement of one of the upper housing covers between its exposed/covered position causes movement of the other upper housing cover to its exposed/covered position. As with the two other known devices described above, the two upper housing cover are moveable in the same two-dimensional plane as each other.

According to certain embodiments of the present invention, but not necessarily all embodiments, there is provided an apparatus comprising a base, first and second parts moveably connected to the base, and a mechanism coupling the first and second parts configured such that when one of the first or second parts is moved relative to the base, the other one of the first or second parts moves relative to the base, wherein one of said first and second parts is configured to tilt to an inclined position relative to the base.

The first part and the second part may be configured to slide relative to the base.

The first part and the second part may be configured to move between an extended position in which the second part extends from the base and the first part is tilted at an angle inclined from the base, and a retracted position in which the first and second parts are positioned proximate to the base.

The apparatus may comprise biasing means configured to bias one of the first and second parts towards the extended position.

The apparatus may comprise a biasing member configured to bias one of the first and second parts towards the extended position.

The apparatus may be configured such that movement of the first or second part from the retracted position to the extended position causes the other of the first or second parts to move from the retracted position to the extended position, and movement of the first or second part from the extended position to the retracted position causes the other of the first or second parts to move from the extended position to the retracted position. In the case where the second part is moved first from the retracted position to the extended position, the second part may be a keypad with integral feature configured to enable the second part to be moved in a first instance. This integral feature may be, for example, a finger slot or cavity in which a finger can pull out the keypad, or other such physical feature or mechanism for extracting the keypad.

The first part may be mounted to the base by a coupling linkage to enable the first part to move from the retracted position to the extended position by sliding relative to the base and tilting relative to the base.

The coupling linkage may include a sliding coupler disposed proximate a front edge of the first part slidably coupling the first part to the base. The coupling linkage may further include a pivotable arm coupling the first part to the base.

The mechanism may comprise a belt extending between the base and the first part and cooperating with the second part. The belt may pass over a first roller member rotatably mounted on the second part and over a second roller member rotatably mounted on the base. Said biasing member may maintain the belt under tension. Said biasing means may maintain the belt under tension.

According to certain embodiments of the invention, but not necessarily all embodiments, the first and second parts may include toothed sections and a gear wheel configured to be rotatably mounted to the base in engagement with the toothed sections of each of the first and second parts.

The toothed section on the first part may include a curved portion to allow the first part to tilt relative to the base while remaining in engagement with the gear wheel.

The first part may include a first component and the base includes a second component coupled with said first component to guide a sliding motion of the first part relative to the base.

The first component may be one of a pin and a slot and the second component may be the other of a pin and a slot, the pin being slidably received in the slot. The slot may include a curved portion configured to guide the first part to tilt relative to the base. Two pins may be provided slidably received in the slot.

The slot may be provided on the first part and the or each pin may be provided on the base. The slot may be straight and an end of the slot proximate the curved portion of the toothed section may be positioned at the centre of radius of the arc of the curved portion of the toothed section.

The slot may be provided on the base and the pin may be provided on the first part. The slot may be straight and the pin may be positioned at the centre of radius of the arc of the curved portion of the toothed section.

The present invention also provides a method of reconfiguring an apparatus for use, the apparatus comprising a base, a first and second parts moveably connected to the base, and a mechanism coupling the first and second parts, the method comprising moving the first or second part relative to the base so that the mechanism causes the other of the first or second parts to move relative to the base and one of said first and second parts tilts relative to the base.

The first part and second part may slide relative to the base.

The first part and the second part may move between an extended position in which the second part extends from the base and the first part is tilted at an angle inclined from the base, and a retracted position in which the first and second parts are positioned proximate to the base.

One of the first and second parts may be biased towards the extended position by a biasing member or by a biasing means.

The apparatus may comprise a portable electronic device and the first part may comprise a display unit and the second part may comprise a keypad.

Embodiments of the present invention will now be described, by way of example only, with reference to the accompanying drawings, in which:

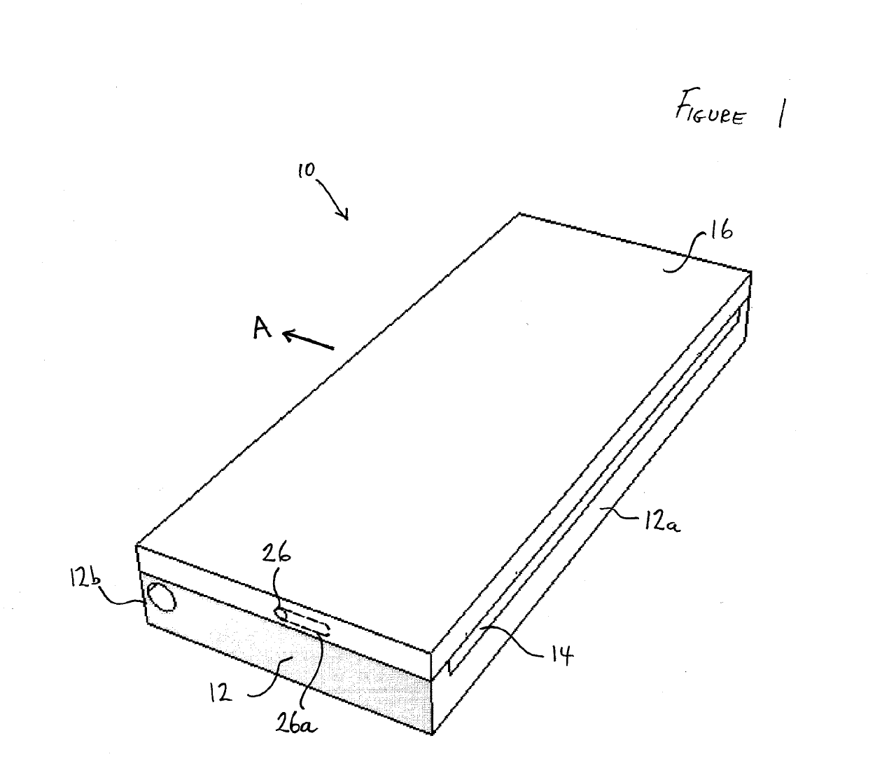

FIG. 1 shows a perspective view of a first embodiment of the invention in a retracted storage position;

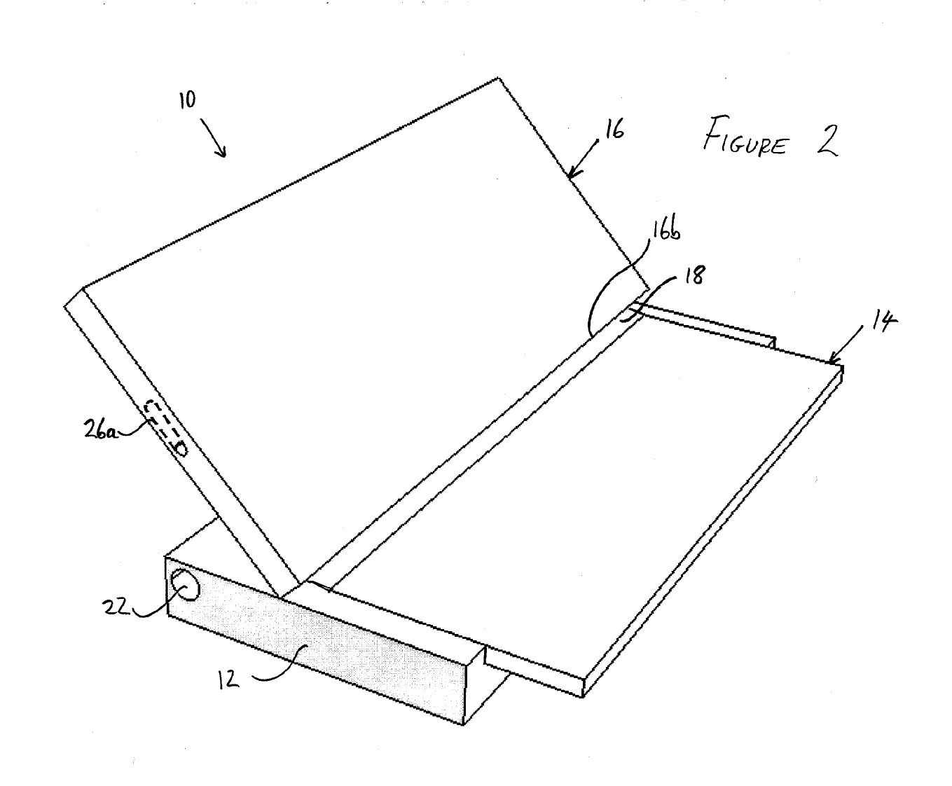

FIG. 2 is a front perspective view of the apparatus of FIG. 1 in an extended operative position;

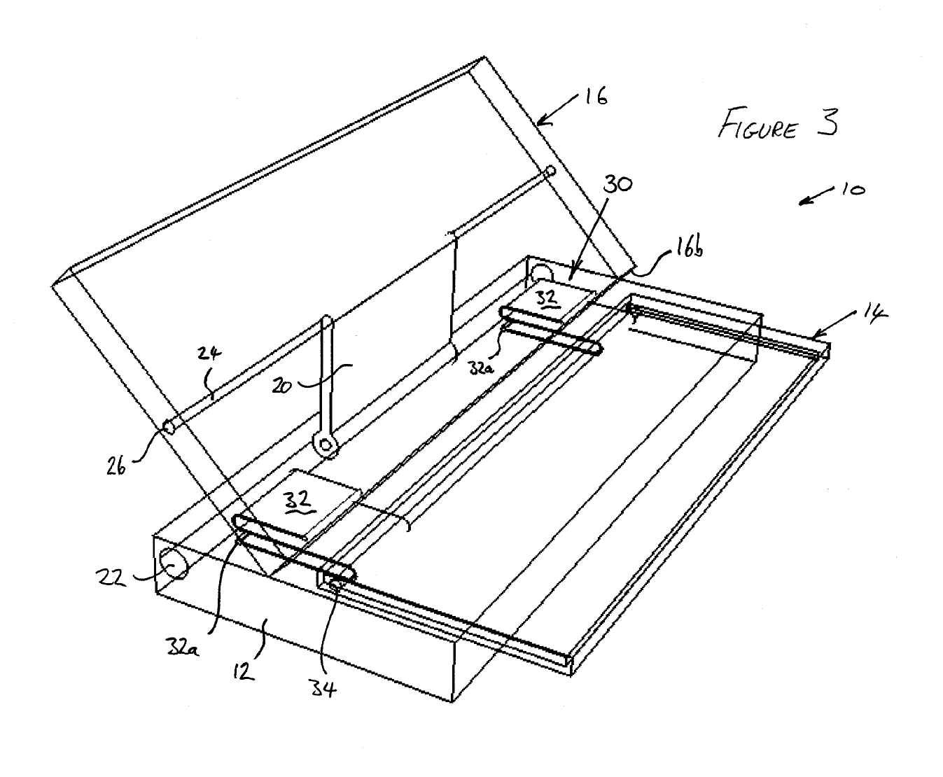

FIG. 3 shows the apparatus of FIG. 2 with internal details visible;

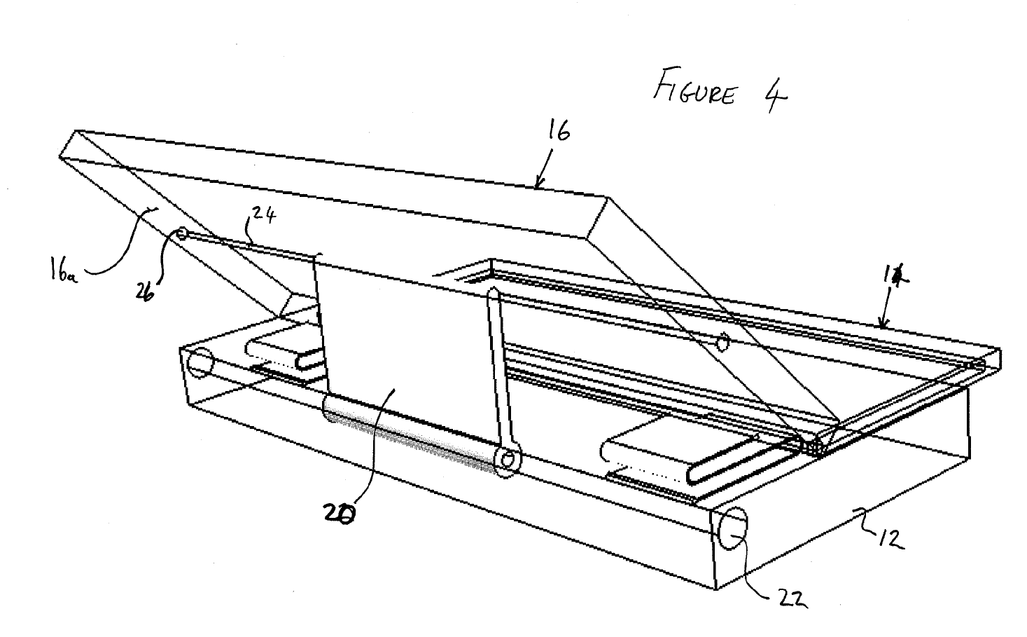

FIG. 4 is a rear perspective view of the apparatus of FIG. 3;

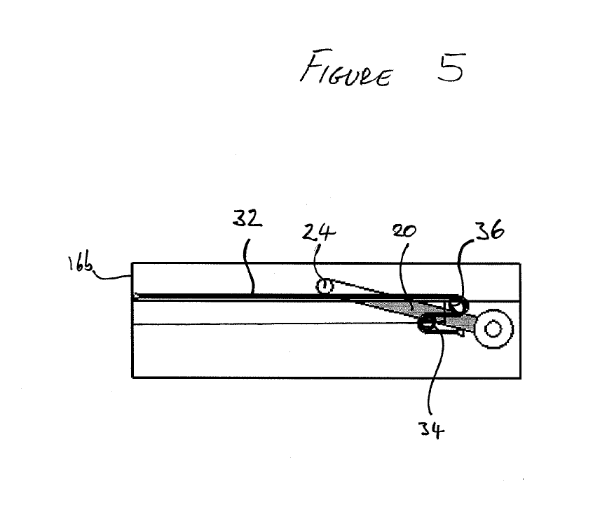

FIG. 5 is a side view of the apparatus shown in FIG. 1;

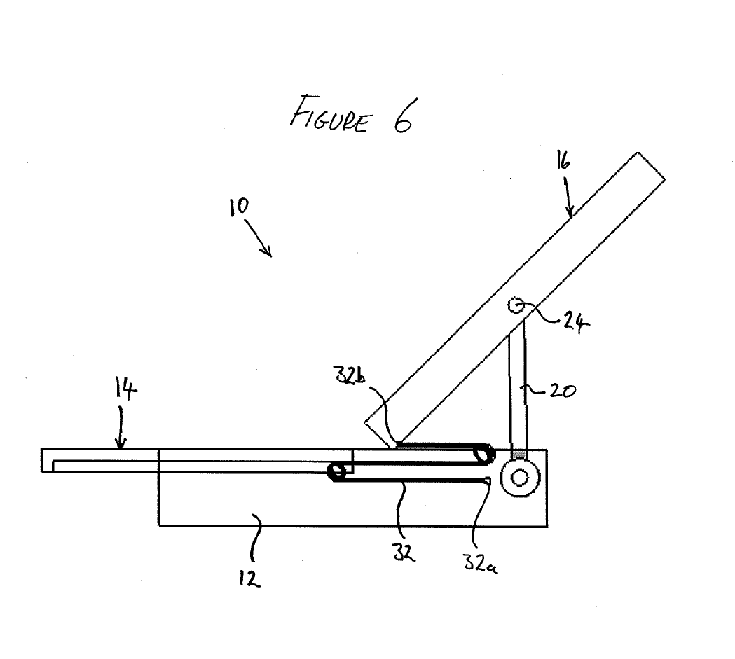

FIG. 6 is a side view of the apparatus shown in FIGS. 2-4;

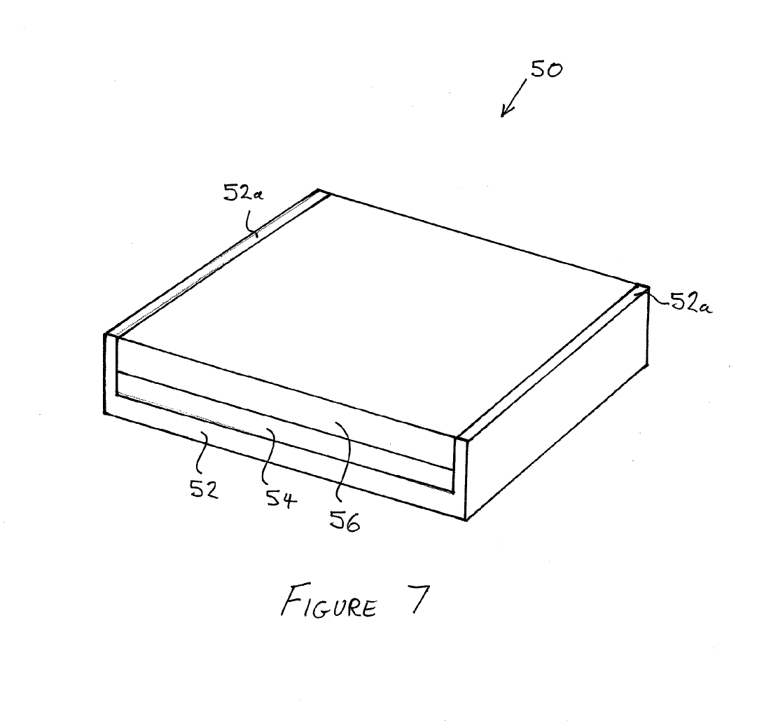

FIG. 7 shows a perspective view of a second embodiment of the invention in a retracted storage position;

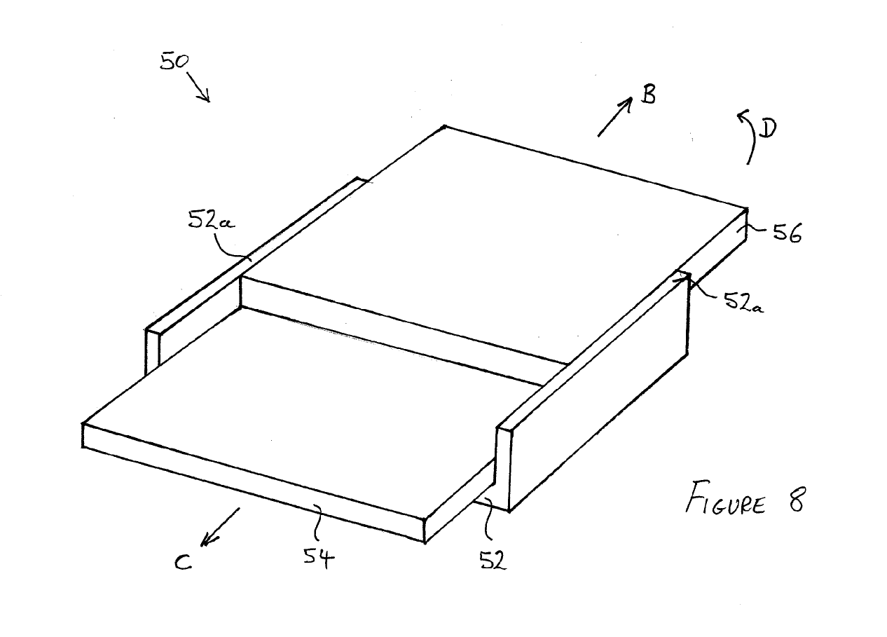

FIG. 8 is a perspective view of the apparatus of FIG. 7 in a partially deployed state between the retracted storage position and an extended operative position;

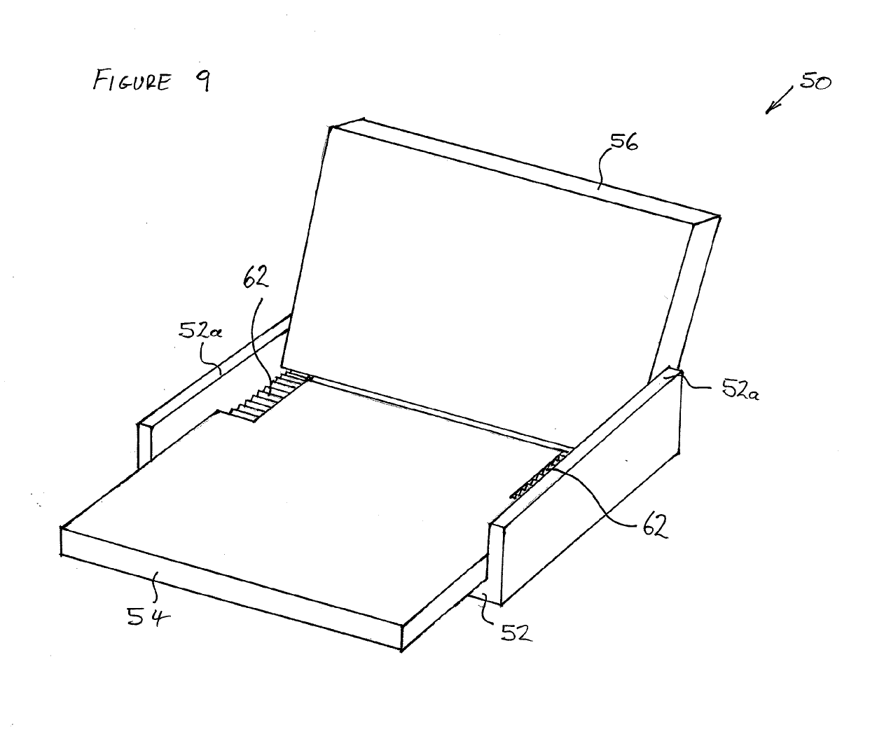

FIG. 9 is a perspective view of the apparatus of FIGS. 7 and 8 in the extended operative position;

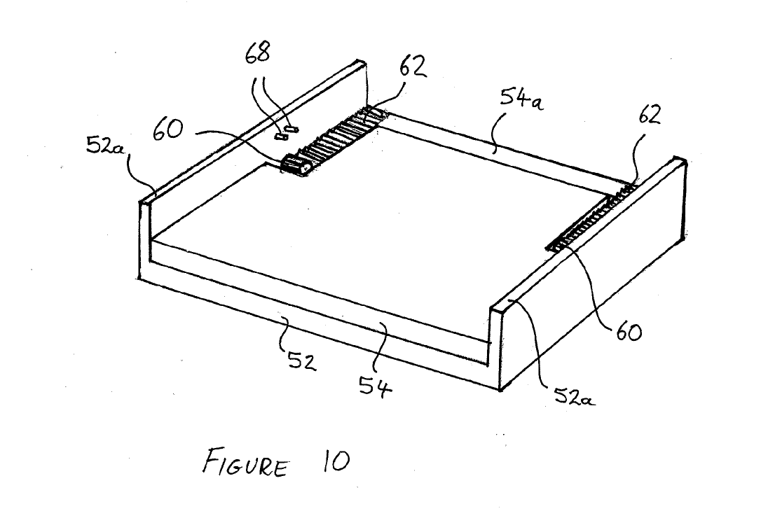

FIG. 10 is a perspective view of the apparatus of FIGS. 7-9 with the display unit removed;

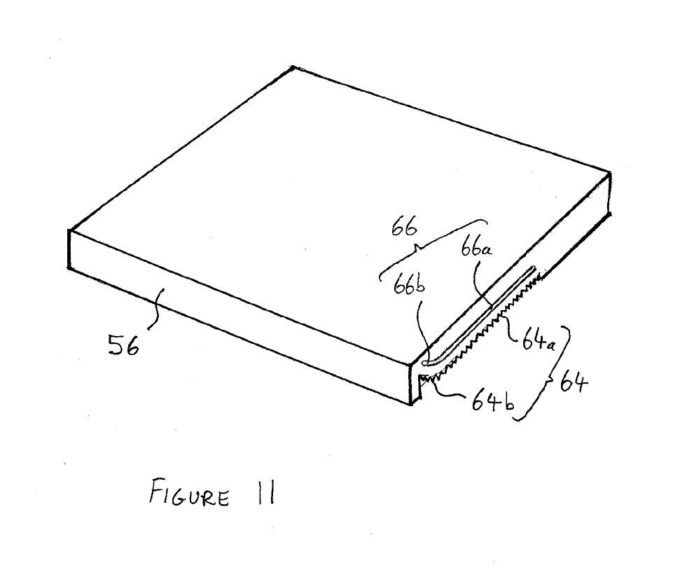

FIG. 11 is a perspective view of the display unit alone of the apparatus of FIGS. 7-9;

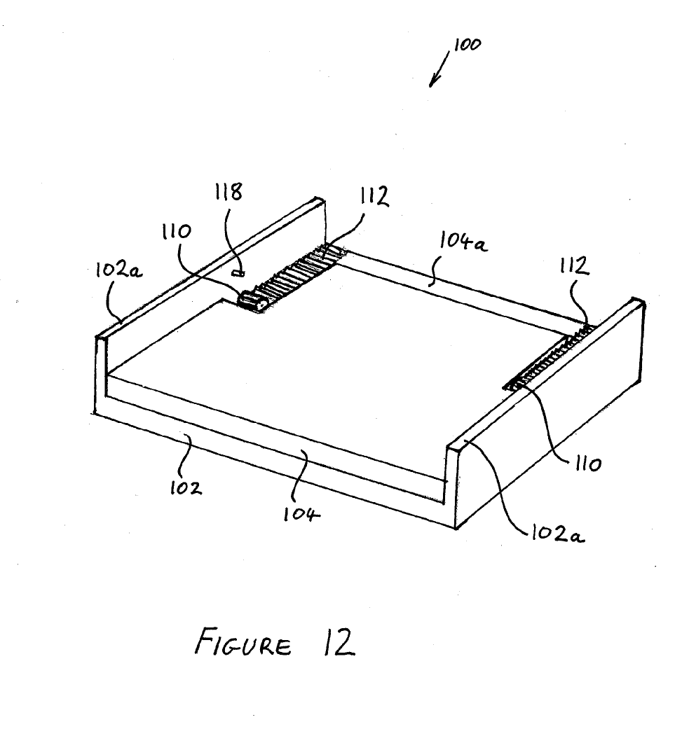

FIG. 12 is a perspective view of an apparatus according to a third embodiment of the invention, similar to the second embodiment of the invention but with a modified opening mechanism, shown with the display unit removed;

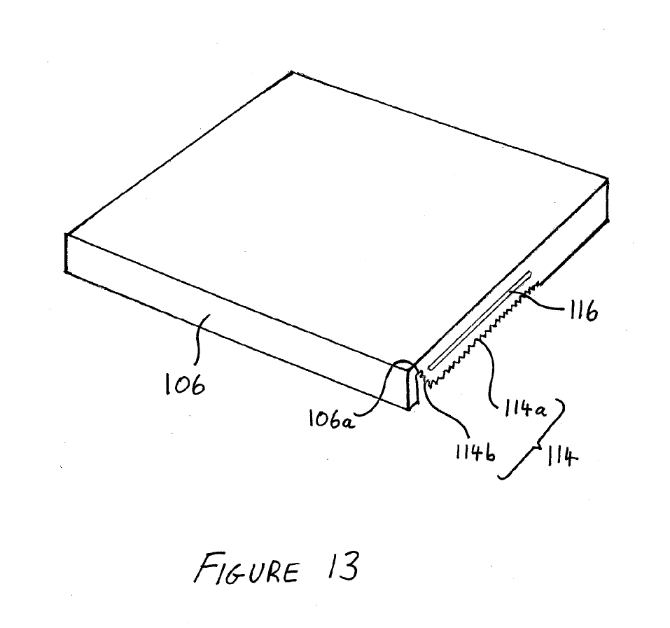

FIG. 13 is a perspective view of the display unit alone of the apparatus of the third embodiment of the invention;

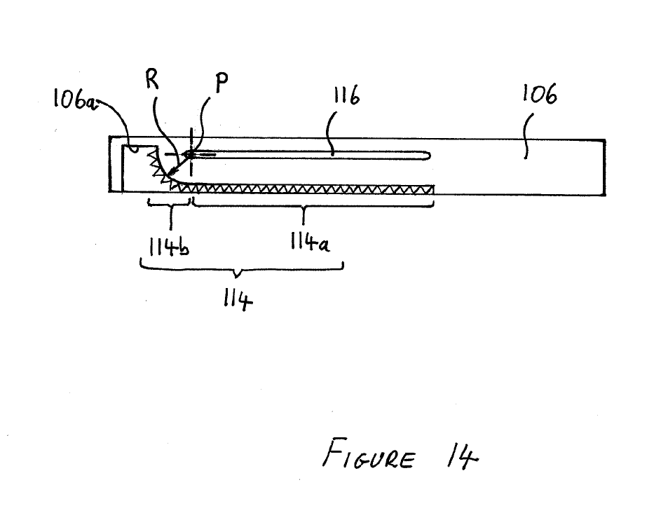

FIG. 14 is a side view of the display unit shown in FIG. 13; and

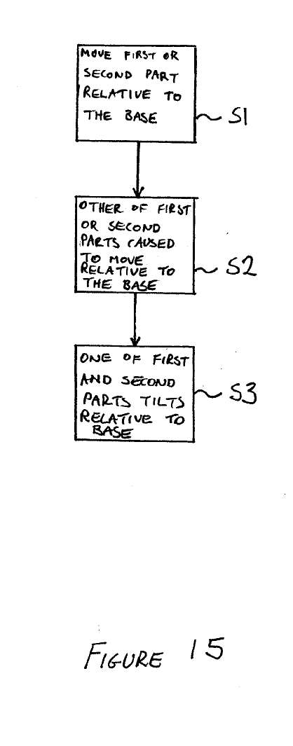

FIG. 15 is a flow chart showing the method of reconfiguring an apparatus of the invention for use.

FIGS. 1-6 show a first embodiment of the present invention illustrating a portable electronic device 10, such as a mobile telephone, mobile computing device or PDA (Personal Digital Assistant), comprising a base 12, a keypad 14 and a display unit 16. The keypad 14 and the display unit 16 are moveably connected to the base 12 such that the keypad 14 is configured to slide relative to the base 12, and the display unit 16 is configured to both slide relative to the base 12 and also pivot relative to the base 12 so as to be inclined at an angle relative to the base 12.

The base 12 has a front edge 12a and a rear edge 12b, and includes a keypad recess 18 open at the front edge 12a to accommodate the keypad 14 and to define its range of sliding motion between a retracted storage position (see FIGS. 1 and 5) in which the keypad 14 is fully received within the keypad recess 18 in the base 12, and an extended operative position (see FIGS. 2-4 and 6) in which the keypad 14 extends from the base 12 out of the keypad recess 18. The base unit 12 includes a biasing member (not shown) which biases the keypad 14 into the extended operative position.

The display unit 16 is mounted to the base 12 so that it is moveable from a retracted storage position (see FIGS. 1 and 5) in which it lies flat against the base 12, to an extended operative position (see FIGS. 2-4 and 6) in which it is slid backwards relative to the base 12 and also inclined at an angle relative to the base 12. The display unit 16 is connected to the base 12 by an arm 20 located proximate the rear edge 12b of the base 12. A first end of the arm 20 is rotatably located in a pivot recess 22 in the base 12, and the opposite end of the arm 20 is pivotally connected to a lower face 16a of the display unit 16 by connecting rod 24 which extends through a connecting bore 26 in the display unit and through an aperture in said opposite end of the arm 20. The display unit 16 is also connected to the base 12 proximate a front edge 16b of the display unit by sliding mechanism (not shown) which allows the front edge 16b of the display unit 16 to slide relative to the base 12, and also allows the display unit 16 to pivot relative to the base 12 about the sliding mechanism.

The keypad 14 and the display unit 16 are connected by a mechanism 30 which links movement of the display unit 16 with movement of the keypad 14. The mechanism 30 comprises a pair of belts 32 formed in a substantially ‘S’-shaped configuration within the base 12. One end of each belt 32a is secured to the base 12 proximate its rear edge 12b. Each belt then extends forwardly to and over a keypad roller 34 which extends though the key pad 14 at its rear edge 14a. Each belt 32 then passes back on itself and over a base roller 36 formed proximate to and disposed above where each belt is secured to the base 12. Each belt then extends forwardly again and its opposite end 32b is secured to a part of the display unit 16 proximate the front edge 16b thereof. Each belt is therefore held under tension by the biasing member (not shown) urging the keypad 14, and thereby the keypad roller 34, forwardly into the extended operative position.

The connecting mechanism 30 and the arm 20 described above, provide the keypad 14 and the display unit 16 of the first embodiment of the invention 10 with cooperative movement as described hereafter.

When the portable electronic device 10 is in the storage position, shown in FIGS. 1 and 5, each belt 32 is in the position shown in FIG. 5, in which the keypad roller 34 is disposed proximate the base roller 36 and a large proportion of each belt 32 is disposed between the front edge 16b of the display unit 16 and the base roller 36.

When a user wishes to operate the device 10 and therefore needs access to the keypad 14 and the display unit 16, the user moves the display unit 16 by sliding it rearwards relative to the base 12 in the direction of arrow ‘A’ in FIG. 1. This movement feeds each belt 32 rearwards allowing each one to pass over the base roller 36 and since the first end 32a of each belt is fixed to the base 12, each belt 32 is pulled over the keypad roller 34, as the keypad 14 is allowed to move forwards under the force of the biasing member (not shown) to the extended operative position. As the user continues to slide the display unit 16 rearwards, the keypad 14 continues to slide out of the base 12 under the force of the biasing member. However, since the lower face 16a of the display 16 is also connected to the base 12 by the pivotable arm 20 as well as by the sliding mechanism (not shown), the movement of the display 16 is guided so that as the front edge 16b of the display unit 16 is drawn rearwards, the arm 20 elevates away from the base 12 and the display unit 16 tilts upwards to be inclined at an angle to the base 12, as shown in FIGS. 2-4 and 6.

The above configuration of the portable electronic device provides the user with the ergonomic benefit of having a screen of the display unit 16 inclined with respect to the keypad 14, thereby making the device 10 much easier to use when, for example, placed on a work surface or held in the hands. Furthermore, the coupled movement of the keypad 14 and the display unit 16 make the opening of the device from the storage position to the operative position simpler, quicker and easier to achieve.

When the user has finished operating the portable electronic device 10 and wishes to retract the keypad 14 and display unit 16 into the storage position, they push the display unit 16 towards the base 12 to make it lie flat against the base 12. This causes the front edge 16b of the display unit to pull each belt 32 forwards as it slides by the sliding mechanism (not shown) relative to the base 12. As the belts 32 are pulled over the base roller 36 which cannot move forward or backwards relative to the base 12, and since the first end 32a of each belt is fixed to the base 12, the keypad roller 34 is pulled rearwards, thereby pulling the keypad 14 into the keypad recess 18 against the biasing force of the biasing member (not shown) and thus into the storage position. When the display unit 16 is fully flush with the base 12, the keypad 14 is fully retracted into the base 12, and so the portable electronic device is back in the storage position as shown in FIGS. 1 and 5. The portable electronic device 10 may include a locking mechanism such as a latch or other conventional locking mechanism to secure the device 10 in the storage position against the biasing force of the biasing member (not shown).

Various modifications are intended to fall within the scope of the invention which could be applied to the first embodiment described above. For example, each belt may be or may incorporate connections and/or wires linking the keypad 14 to the display unit 16. This would mean that the belts would have the dual purpose of operating the coordinated opening and closing of the portable electronic device 10, as well as providing the electrical connection between the two components, thereby saving space in the device.

Furthermore, the connecting rod 24 in the display unit 16 may be located in a connecting slot rather than a connecting bore 26 (see reference 26a in dashed lines in FIGS. 1 and 2). The would allow the motion of the display unit 16 to initially slide rearwards flush with the base 12 when the device 10 is moved to the operative position, before it then tilts relative to the base 12, as the connecting rod 24 slides within the connecting slot 26a, until the connecting rod 24 reaches the end of the connecting bore and the arm 20 is then forced to tilt upwards away from the base 12, thereby causing the display unit 16 to tilt upwards.

FIGS. 7-11 show a second embodiment of the present invention and which illustrate a portable electronic device 50 comprising a base 52, a keypad 54 and a display unit 56. The base includes upstanding lateral side wall portions 52a along two opposite side edges thereof. The keypad 54 and the display unit 56 are slidingly coupled to a the base 52 between the side walls 52a and are coupled to each other by a cooperating mechanism 58, and are moveable between a retracted storage position (see FIG. 7) in which the keypad 54 and the display 56 are located into alignment with the base 52 and with each other, and an extended operative position (see FIG. 9) in which the keypad 54 extends from the front of the base 52 and the display unit 56 is displaced rearwards and tilted relative to the base 52 and keypad 54.

The cooperating mechanism 58 of the device 50 comprises a pair of cogs 60 rotatably mounted to the side walls 52a of the base 52 and a pair of toothed racks 62 formed integrally with the keypad 54 at lateral rear portions thereof such that the cogs 60 engage with the toothed racks 62 and are caused to rotate as the key pad 54 is slid between the storage and operative positions. The toothed racks are recessed slightly into the upper surface of the keypad 54. The cooperating mechanism 58 further comprises a toothed runner 64 formed on each lateral edge of the display unit 56. The toothed runners 64 comprise a straight section 64a along the majority of their length, and a short curved section 64b proximate a front edge of the display unit 56. The toothed runners 64 are configured to engage with the cogs 60 of the base 52 such that as the keypad 54 is moved between the storage and operative positions, the cogs 60 are caused to rotate, and so the display unit 56 is caused to move between the storage and operative positions. Correspondingly, vice versa, as the display unit 56 is moved between the storage and operative positions, the cogs 60 are caused to rotate, and so the keypad 54 is caused to move between the storage and operative positions.

The display unit 56 includes a guide slot 66 on each lateral side above each toothed runner 64, which are shaped similarly to the toothed runners with a straight section 66a along the majority of the slot length and a curved section 66b at one end thereof adjacent the curved section 64b of the respective toothed runner 64. Each side wall 52a of the base unit 52 includes a pair of guide pins 68 which project inwardly therefrom and are received in the guide slot 66 in the corresponding side of the display unit 56. Thereby, the guide pins 68 located in the guide slots 66 define the range of motion of the display unit 56 between the storage and operative positions as will be described in more detail below. Furthermore, since the keypad 54 is mechanically coupled with the display unit 56 by the cooperating mechanism 58, the range of motion of the keypad 54 is also defined.

When the portable electronic device 50 is not in use, it is kept in the storage position as shown in FIG. 7, in which the keypad 54 is retracted into alignment with the base 52 and the display unit 56 is retracted and lies flat against the keypad 54. When a user wishes to use the portable electronic device 50, they initially slide the display unit 56 rearwards relative to the base 52 in the direction shown by arrow ‘B’ in FIG. 8. The display unit 56 slides with the guide pins 68 within the guide slots 66 and in the initial part of the movement of the display unit 56, the guide pins 68 are received in the straight section 66a of the guide slots 66 so that the display unit 56 remains flat. As the display unit 56 is slid back, the straight section 64a of the toothed runners 64 engage with the cogs 60, which in turn engage with the toothed racks 62 of the keypad 54, thereby causing the keypad 54 to slide forwards relative to the base 52 in the direction of arrow ‘C’ in FIG. 8. The keypad 54 is slidably coupled to the base 52 by a suitable mechanism (not shown) such as a guide rail or other known constructional feature.

As the user continues to move the display unit 56 rearwards, it is guided by the guide pins 68 located in the curved sections 66b of the guide slots 66 so that it then tilts upwards in the direction shown by arrow ‘D’ in FIG. 8 and into the operative position shown in FIG. 9. As the display unit 56 tilts upwards, the curved sections 64b of the toothed runners 64 remain in engagement with the cogs 60 and thereby continue to rotate the cogs 60, thereby continuing to extend the keypad 54 in the direction of arrow ‘C’ until the guide pins 68 reach the end of the curved section 66b of the guide slots 66, at which point the portable electronic device 50 is fully in the operative position with the keypad 54 fully extended. It will be noted that the keypad 54 includes a recessed section 54a along its rear edge such that when the display unit 56 tilts to the operative position, the lower front-most edge of the display unit 56 does not contact and foul against the keypad 54, but locates within the recess 54a.

When a user has finished using the portable electronic device 50, they reverse the process described above to close the display unit 56 which thereby retracts the keypad 54, and so the device is returned to the storage position shown in FIG. 7.

The portable electronic devices may be provided with a locking mechanism (not shown) such as a latch, which is operable to secure the device in the operative and/or storage position.

The location of the guide pins 68 and guide slots 66 may be reversed within the scope of the invention—such that the guide pins 68 may be provided on the display part 56 and the guide slots 66 may be provided on the base 52.

FIGS. 12-14 show a third embodiment of the present invention, which is similar to the second embodiment shown in FIGS. 7-11, and which illustrate a portable electronic device 100 comprising a base 102, a keypad 104 and a display unit 106. The keypad 104 is slidably coupled to the base 102 by a suitable mechanism (not shown) such as a guide rail or other known constructional feature The base 102 includes upstanding lateral side wall portions 102a along two opposite side edges thereof. The keypad 104 and the display unit 106 are slidingly coupled to a the base 102 between the side walls 102a and are coupled to each other by a cooperating mechanism 108, and are moveable between a retracted storage position (which is identical to that of the second embodiment of the invention shown in FIG. 7) in which the keypad 104 and the display 106 are located into alignment with the base 102 and with each other, and an extended operative position (which is identical to that of the second embodiment of the invention shown in FIG. 9) in which the keypad 104 extends from the front of the base 102 and the display unit 106 is displaced rearwards and tilted relative to the base 102 and keypad 104.

The difference between the second and third embodiments of the invention lies in the configuration of the cooperating mechanism 108, which will be explained hereafter. The cooperating mechanism 108 comprises a pair of cogs 110 rotatably mounted to the side walls 102a of the base 102 and a pair of toothed racks 112 formed integrally with the keypad 104 at lateral rear portions thereof such that the cogs 110 engage with the toothed racks 112 and are caused to rotate as the key pad 104 is slid between the storage and operative positions. The toothed racks 112 are recessed slightly into the upper surface of the keypad 104. The cooperating mechanism 108 further comprises a toothed runner 114 formed on each lateral edge of the display unit 106. The toothed runners 114 comprise a straight section 114a along the majority of their length, and a short curved section 114b proximate a front edge of the display unit 106. The toothed runners 114 are configured to engage with the cogs 110 of the base 102 such that as the keypad 104 is moved between the storage and operative positions, the cogs 110 are caused to rotate, and so the display unit 106 is caused to move between the storage and operative positions. Correspondingly, vice versa, as the display unit 106 is moved between the storage and operative positions, the cogs 110 are caused to rotate, and so the keypad 104 is caused to move between the storage and operative positions.

It will be appreciated that the above-described features of the cooperating mechanism 108 are identical to those of the cooperating mechanism 58 of the second embodiment. However, the display unit 106 includes a guide slot 116 on each lateral side above each toothed runner 114, but they are not shaped similarly to the toothed runners 114 as with the second embodiment of the invention, but instead, are straight along their entire length. The end of the each guide slot 116 proximate the curved section 114b of each toothed runner 114 is positioned at a centre point ‘P’ of the radius ‘R’ of the arc of the curved section 114b of each toothed runner 114, as shown in FIG. 14.

Each side wall 102a of the base unit 102 includes a single guide pin 118 (as opposed to the pair of guide pins 58 present in the second embodiment of the invention) which project inwardly from each side wall 102a and are received in the guide slot 116 in the corresponding side of the display unit 106. Thereby, the guide pins 118 located in the guide slots 116 define the range of motion of the display unit 106 between the storage and operative positions as will be described in more detail below. Furthermore, since the keypad 104 is mechanically coupled with the display unit 106 by the cooperating mechanism 108, the range of motion of the keypad 104 is also defined.

When the portable electronic device 100 is not in use, it is kept in the storage position, as shown in FIG. 7 and described above in relation to the second embodiment. When a user wishes to use the portable electronic device 100, they initially slide the display unit 106 rearwards as with the second embodiment, so the display unit 106 slides with the guide pins 118 within the guide slots 116. As the display unit 106 is slid back, the toothed runners 114 engage with the cogs 110, which in turn engage with the toothed racks 112 of the keypad 104, thereby causing the keypad 104 to slide forwards relative to the base 102, as previously described. As the user continues to move the display unit 106 rearwards, the guide pins 118 reach the end of the guide slots 116 which corresponds to the end of the straight section 114a of the toothed runners 114. After this point, the user tilts the display unit 106 upwards and into the operative position. As the display unit 106 tilts upwards, it pivots about the guide pins 118 located at the end of the guide lots 116. As the end of the guide slots 116 are positioned at the centre point P of the radius R of the arc of the curved sections 114b of the toothed runners 114, the curved sections 114b of the toothed runners 114 remain in engagement with the cogs 110 and thereby continue to rotate the cogs 110, thereby continuing to extend the keypad 104 into the operative position until the cog 110 abuts an end wall 106a of the display unit 106 at the end of the curved section 114b of the toothed runners 114. At this point the portable electronic device 100 is fully in the operative position with the keypad 104 fully extended. It will be noted that the keypad 104 includes a recessed section 104a along its rear edge such that when the display unit 106 tilts to the operative position, the lower front-most edge of the display unit 106 does not contact and foul against the keypad 104, but locates within the recess 104a.

When a user has finished using the portable electronic device 100, they reverse the process described above to close the display unit 106 which thereby retracts the keypad 104, and so the device is returned to the storage position.

The portable electronic devices may be provided with a locking mechanism (not shown) such as a latch, which is operable to secure the device in the operative and/or storage position.

The location of the guide pins 118 and guide slots 116 may be reversed within the scope of the invention—such that the guide pins 118 may be provided on the display part 106 and the guide slots 116 may be provided on the base 102.

FIG. 15 shows a method of reconfiguring an apparatus of the invention. S1 involves moving one of a first or second part relative to the base. In the exemplary embodiments shown and described above, said first part is a display unit and said second part is a keypad. S2 shows the other of the first and second parts being caused to move relative to the base by the mechanism which couples the first and second parts, as the one of the first and second parts is moved. S3 shows one of the first and second parts tilting relative to the base. In the exemplary embodiments shown and described above, the display unit tilts relative to the base.

In the above description, it is illustrated that the display unit may be manipulated between a retracted position and an extended position which causes the mechanism coupling the display unit to the keypad to move the key pad respectively between a retracted position and an extended position. However, it is intended within the scope of the invention that the keypad may be manipulated by a user to move between a retracted position and an extended position, which then causes the mechanism coupling the display unit to the keypad to move the display unit respectively between a retracted position and an extended position. In such an embodiment, it is envisaged that the keypad may include some feature to facilitate movement of the keypad from the retracted position to the extended position, such as, for example, a finger slot or cavity to enable a user to withdraw the keypad.

It will be appreciated that the above description comprises exemplary embodiments only and variations and modifications are intended to fall within the scope of the invention, defined in the claims hereafter.

1-29. (canceled)

30. An apparatus comprising a base, first and second parts moveably connected to the base, and a mechanism coupling the first and second parts configured such that when one of the first and second parts is moved relative to the base, the other one of the first and second parts moves relative to the base, wherein one of the first and second parts is configured to slide in at least one of a direction toward and a direction away from the other one of the first and second parts, and wherein one of the first and second parts is configured to tilt to an inclined position relative to the base.

31. An apparatus according to claim 30 wherein the first part and the second part are slidable relative to the base.

32. An apparatus according to claim 31 wherein the first part and the second part are moveable between an extended position in which the second part extends from the base and the first part is tilted at an angle inclined from the base, and a retracted position in which the first and second parts are positioned proximate to the base.

33. An apparatus according to claim 32 comprising a biasing member configured to bias one of the first and second parts towards the extended position.

34. An apparatus according to claim 32 configured such that movement of one of the first and second parts from the retracted position to the extended position causes the other one of the first and second parts to move from the retracted position to the extended position, wherein movement of one of the first and second parts from the extended position to the retracted position causes the other one of the first and second parts to move from the extended position to the retracted position.

35. An apparatus according to claim 32 wherein the first part is mounted to the base by a coupling linkage to enable the first part to move from the retracted position to the extended position by sliding relative to the base and tilting relative to the base.

36. An apparatus according to claim 35 wherein the coupling linkage includes a sliding coupler disposed proximate a front edge of the first part slidably coupling the first part to the base.

37. An apparatus according to claim 36 wherein the coupling linkage further includes a pivotable arm coupling the first part to the base.

38. An apparatus according to claim 30 wherein the mechanism comprises a belt extending between the base and the first part and cooperating with the second part.

39. An apparatus according to claim 38 wherein the belt passes over a first roller member rotatably mounted on the second part and over a second roller member rotatably mounted on the base.

40. An apparatus according to claim 33 wherein the mechanism coupling the first and second parts comprises a belt extending between the base and the first part and cooperating with the second part, wherein said biasing member maintains the belt under tension.

41. An apparatus according to claim 40 wherein the belt passes over a first roller member rotatably mounted on the second part and over a second roller member rotatably mounted on the base.

42. An apparatus according to claim 30 wherein the apparatus comprises a portable electronic device and the first part comprises a display unit and the second part comprises a keypad.

43. A method of reconfiguring an apparatus for use, the apparatus comprising a base, first and second parts moveably connected to the base, and a mechanism coupling the first and second parts, the method comprising moving one of the first and second parts relative to the base so that the mechanism causes the other one of the first and second parts to move relative to the base, wherein one of the first and second parts slides in at least one direction toward and a direction away from the other one of the first and second parts, and wherein one of the first and second parts is configured to tilts relative to the base.

44. A method according to claim 43 wherein the first part and second part slide relative to the base.

45. A method according to claim 43 wherein the first part and the second part move between an extended position in which the second part extends from the base and the first part is tilted at an angle inclined from the base, and a retracted position in which the first and second parts are positioned proximate to the base.

46. A method according to claim 45 wherein one of the first and second parts is biased towards the extended position by a biasing member.

47. A method according to claim 43 wherein the apparatus comprises a portable electronic device and the first part comprises a display screen and the second part comprises a keypad.

48. An apparatus according to claim 30 wherein one of the first and second parts is exclusively slidable relative to the base and the other of the first and second parts is both slidable relative to the base and tiltable relative to the base.

49. An apparatus according to claim 30 wherein the first and second parts are slidable in opposite directions relative to each other.

50. A portable electronic device comprising a base, display unit and a keypad moveably connected to the base, and a mechanism coupling the display unit and keypad configured such that when one of the display unit and keypad is moved relative to the base, the other one of the display unit and keypad moves relative to the base, wherein one of the display unit and keypad is configured to slide in at least one direction toward and a direction away from the other one of the display unit and keypad, wherein one of the display unit and keypad is configured to tilt to an inclined position relative to the base.
